(19) United States
(12) Patent Application Publication
(10) Pub. No.: US 2024/0352289 A1
(43) Pub. Date: Oct. 24, 2024

(54) THERMALLY CONDUCTIVE FILM ADHESIVE COMPOSITION AND THERMALLY CONDUCTIVE FILM ADHESIVE, AND SEMICONDUCTOR PACKAGE USING THERMALLY CONDUCTIVE FILM ADHESIVE AND PRODUCING METHOD THEREOF

(71) Applicant: FURUKAWA ELECTRIC CO., LTD., Tokyo (JP)

(72) Inventors: Minoru MORITA, Tokyo (JP); Shunya OHBUCHI, Tokyo (JP)

(73) Assignee: FURUKAWA ELECTRIC CO., LTD., Tokyo (JP)

(21) Appl. No.: 18/756,411

(22) Filed: Jun. 27, 2024

Related U.S. Application Data
(63) Continuation of application No. PCT/JP2023/012170, filed on Mar. 27, 2023.

(30) Foreign Application Priority Data
Mar. 30, 2022 (JP) 2022-055427

(51) Int. Cl. C09J 163/00; C09J 5/06; C09J 11/04; C09J 11/06; H01L 21/683

(52) U.S. Cl. CPC C09J 163/00; C09J 5/06; C09J 11/04; C09J 11/06; H01L 21/6836

(57) ABSTRACT

A thermally conductive film adhesive composition including an epoxy resin (A), an epoxy resin curing agent (B), a polymer component (C), a polyhedral alumina filler (D), and a silane coupling agent (E), wherein a percentage of the polyhedral alumina filler (D) to a total content of the epoxy resin (A), the epoxy resin curing agent (B), the polymer component (C), the polyhedral alumina filler (D), and the silane coupling agent (E) is from 20 to 70 vol %, and wherein a blending multiple of the silane coupling agent is from 1.0 to 10;
a film adhesive using the composition;
a semiconductor package; and
a producing method thereof.

### CROSS-REFERENCE TO RELATED APPLICATIONS

This application is a Continuation of PCT International Application No. PCT/JP2023/012170 filed on Mar. 27, 2023, which claims priority under 35 U.S.C. § 119 (a) to Japanese Patent Application No. 2022-055427 filed in Japan on Mar. 30, 2022. Each of the above applications is hereby expressly incorporated by reference, in its entirety, into the present application.

### FIELD OF THE INVENTION

The present invention relates to a thermally conductive film adhesive composition and a thermally conductive film adhesive as well as a semiconductor package using the thermally conductive film adhesive and a producing method thereof.

### BACKGROUND OF THE INVENTION

Stacked MCPs (Multi Chip Package) in which semiconductor chips are multistacked have recently been widely spread. Such stacked MCPs are mounted on memory packages for mobile phones or portable audio devices. Further, along with multi-functionality of mobile phones and the like, high densification and high integration of the package have also been advanced. Along with such advance, multistacking of the semiconductor chips has been advanced.

Thermosetting film adhesives (die attach films, die bond films) have been used for bonding a circuit board and a semiconductor chip or bonding semiconductor chips in the production process of such a memory package.

Along with multistacking of the chips, the die attach film is required to have an increasingly thinner form. Also, as miniaturization in the wiring rule of the wafer has been advanced, heat is more likely to be generated on the surface of the semiconductor element. Therefore, in order to dissipate heat to the outside of the package, a thermally conductive filler is blended in the die attach film to realize high thermal conductivity.

As a material of a thermosetting film adhesive intended for so-called die attach film applications, for example, a composition obtained by combining an epoxy resin, a curing agent for the epoxy resin, a polymer compound, and an inorganic filler (inorganic filler) is known (e.g., Patent Literatures 1 and 2).

### CITATION LIST

### Patent Literature

Patent Literature 1: JP-A-2014-234482 (“JP-A” means unexamined published Japanese patent application)
Patent Literature 2: WO 2021/033368

### SUMMARY OF INVENTION

### Technical Problem

As one of means for realizing a highly thermally conductive die attach film, it is conceivable to blend a larger amount of thermally conductive inorganic filler. The present inventors have further studied an inorganic filler-containing adhesive composition by focusing on the type and shape of the inorganic filler, and have found that the use of polyhedral alumina filler can achieve a higher thermal conductivity than the case of using the spherical alumina filler used in Patent Literatures 1 and 2. On the other hand, it has been found that blending of the polyhedral alumina filler makes it difficult to exhibit stable adhesion strength, and causes a problem that sufficient strength of adhesion to an adherend cannot be obtained.

The present invention provides a thermally conductive film adhesive that contains a polyhedral alumina filler as an inorganic filler and exhibits excellent thermal conductivity and excellent strength of adhesion to an adherend as well as a thermally conductive film adhesive composition suitable for preparing this film adhesive. In addition, the present invention provides a semiconductor package using the thermally conductive film adhesive and a producing method thereof.

### Solution to Problem

The present inventors have conducted intensive research in view of the above problems, and, as a result, have found that the above problems can be solved by including a silane coupling agent, in an excessive amount within a specific range based on a polyhedral alumina filler, into an adhesive composition containing the polyhedral alumina filler in addition to an epoxy resin, an epoxy resin curing agent, and a polymer component.

The present invention is based on the above findings, and after further investigation, has been completed.

The above problems of the present invention have been solved by the following means.

[1]

A thermally conductive film adhesive composition, containing at least:
an epoxy resin (A),
an epoxy resin curing agent (B),
a polymer component (C),
a polyhedral alumina filler (D), and
a silane coupling agent (E),
   wherein a percentage of the polyhedral alumina filler (D) to a total content of the epoxy resin (A), the epoxy resin curing agent (B), the polymer component (C), the polyhedral alumina filler (D), and the silane coupling agent (E) is from 20 to 70 vol %, and
   wherein a blending multiple of the silane coupling agent as represented by the following (Formula I) is from 1.0 to 10:

Blending multiple of silane coupling agent=Blending amount(g) of silane coupling agent(E)/Required amount(g) of silane coupling agent(E) where (Formula I)

Required amount(g) of silane coupling agent(E)=[Blending amount(g) of polyhedral alumina filler(D)×Specific surface area(m²/g) of polyhedral alumina filler(D)]/Minimum coating area(m²/g) of silane coupling agent(E). (Formula II)

[2]

The thermally conductive film adhesive composition described in [1], wherein when a thermally conductive film adhesive obtained from the thermally conductive film adhesive composition is heated at a temperature elevation rate of 5° C./min from 25° C., melt viscosity at 120° C. reaches a range of 250 to 10000 Pa·s and
wherein the thermally conductive film adhesive has a thermal conductivity of 1.0 W/m·K or more.
   [3]

The thermally conductive film adhesive composition described in [1] or [2], wherein the thermally conductive film adhesive has a die shear strength at 25° C. of 20 MPa or more.

[4]

The thermally conductive film adhesive composition described in any one of [1] to [3], wherein a percentage of the polyhedral alumina filler (D) to a total content of the epoxy resin (A), the epoxy resin curing agent (B), the polymer component (C), the polyhedral alumina filler (D), and the silane coupling agent (E) is from 50 to 70 vol %.

[5]

A thermally conductive film adhesive which is obtained from the thermally conductive film adhesive composition described in any one of [1] to [4].

[6]

The thermally conductive film adhesive described in [5], which has a thickness in a range of 1 to 80 μm.

[7]

A method of producing a semiconductor package, including:
a first step of providing an adhesive layer by thermocompression bonding the thermally conductive film adhesive described in [5] or [6] to a back surface of a semiconductor wafer in which a semiconductor circuit is formed on a surface, and providing a dicing film with the adhesive layer interposed between the back surface and the dicing film;
a second step of integrally dicing the semiconductor wafer and the adhesive layer to obtain a semiconductor chip with an adhesive layer, the semiconductor chip including the semiconductor chip and a piece of the film adhesive on the dicing film;
a third step of removing the dicing film from the semiconductor chip with an adhesive layer and thermocompression bonding the semiconductor chip with an adhesive layer and a circuit board via the adhesive layer; and
a fourth step of thermally curing the adhesive layer.
   [8]

A semiconductor package which is obtained by the producing method described in [7].

In the present invention, the numerical ranges expressed with the term “to” refer to ranges including, as the lower limit and the upper limit, the numerical values before and after the term “to”.

### Advantageous Effects of Invention

The thermally conductive film adhesive of the present invention contains a polyhedral alumina filler as an inorganic filler, and exhibits excellent thermal conductivity and excellent strength of adhesion to an adherend. The thermally conductive film adhesive composition of the present invention is suitable for providing the above thermally conductive film adhesive.

The method of producing a semiconductor package according to the present invention makes it possible to produce a semiconductor package with excellent thermal conductivity and excellent adhesion reliability.

### BRIEF DESCRIPTION OF DRAWINGS

FIG. 1 is a schematic longitudinal cross-sectional view illustrating a preferred embodiment of a first step of a method of producing a semiconductor package of the present invention.

FIG. 2 is a schematic longitudinal cross-sectional view illustrating a preferred embodiment of a second step of a method of producing a semiconductor package of the present invention.

FIG. 3 is a schematic longitudinal cross-sectional view illustrating a preferred embodiment of a third step of a method of producing a semiconductor package of the present invention.

FIG. 4 is a schematic longitudinal cross-sectional view illustrating a preferred embodiment of a step of connecting a bonding wire of a method of producing a semiconductor package of the present invention.

FIG. 5 is a schematic longitudinal cross-sectional view illustrating an example of an embodiment of multistacking of a method of producing a semiconductor package of the present invention.

FIG. 6 is a schematic longitudinal cross-sectional view illustrating an example of an embodiment of another multistacking of a method of producing a semiconductor package of the present invention.

FIG. 7 is a schematic longitudinal cross-sectional view illustrating a preferred embodiment of a semiconductor package produced by a method of producing a semiconductor package of the present invention.

### DESCRIPTION OF EMBODIMENTS

### [Thermally Conductive Film Adhesive Composition]

The thermally conductive film adhesive composition of the present invention (hereinafter, also referred to as an adhesive composition of the present invention) is a composition suitable for forming a thermally conductive film adhesive of the present invention (hereinafter, referred to as a film adhesive of the present invention).

The adhesive composition of the present invention contains at least an epoxy resin (A), an epoxy resin curing agent (B), a polymer component (C), a polyhedral alumina filler (D), and a silane coupling agent (E). In addition, the percentage of the polyhedral alumina filler (D) to a total content of the epoxy resin (A), the epoxy resin curing agent (B), the polymer component (C), the polyhedral alumina filler (D), and the silane coupling agent (E) is controlled to be from 20 to 70 vol %. Furthermore, the content of the silane coupling agent (E) is controlled so that the blending multiple of the silane coupling agent as represented by the following (Formula I) is from 1.0 to 10.

Blending multiple of silane coupling agent=Blending amount(g) of silane coupling agent(E)/Required amount(g) of silane coupling agent(E) where (Formula I)

Required amount(g) of silane coupling agent(E)=(Blending amount(g) of polyhedral alumina filler(D)×Specific surface area(m²/g) of polyhedral alumina filler(D))/Minimum coating area(m²/g) of silane coupling agent(E) (Formula II)

The specific surface area of the polyhedral alumina filler (D) is a value measured by the Brunauer-Emmett-Teller method (BET method) in accordance with JIS Z 8830:2013 (ISO 9277:2010) “Carrier gas method” using nitrogen gas.

As the measurement conditions, the conditions described in Examples can be adopted.

The minimum coating area of the silane coupling agent (E) means an area where the silane coupling agent (E) covers the material surface when 1 g of the silane coupling agent (E), for example, is reacted and adsorbed on the material surface. Specifically, the following equation is used for calculation:

Minimum coating area(m²/g)=6.02×10²³×13×10⁻²⁰/Molecular weight of silane coupling agent.

The adhesive composition of the present invention is in a pre-curing state. Thus, the blending multiple of the silane coupling agent and the blending amount of the silane coupling agent (E) as represented by the above (Formula I) are each a value in a pre-curing adhesive composition in the present invention. The meaning of “pre-curing” is the same as the meaning of “pre-curing” for “thermally conductive film adhesive” described later.

When the blending multiple of the silane coupling agent is within the above range, it is possible to further increase the strength of adhesion to an adherend while exploiting excellent thermal conductivity caused by the wide contact area of the polyhedral alumina filler (D). In addition, when the film adhesive of the present invention is incorporated into a semiconductor package, voids are less likely to be generated between the film adhesive and an adherend.

The blending multiple of the silane coupling agent is preferably from 1.1 to 9.0, more preferably from 1.3 to 8.0, still more preferably from 1.5 to 7.0, particularly preferably from 1.5 to 4.0, and most preferably from 1.6 to 2.5.

In addition, the required amount of the silane coupling agent (E) is preferably from 0.20 to 3.50 g, more preferably from 0.40 to 3.20 g, still more preferably from 0.60 to 3.10 g, still more preferably from 0.60 to 3.00 g, still more preferably from 0.80 to 2.00 g, and particularly preferably from 0.90 to 1.55 g. The required amount of the silane coupling agent (E) may be from 0.90 to 3.20 g or from 1.40 to 3.10 g.

Hereinafter, each component contained in the adhesive composition will be described.

### <Epoxy Resin (A)>

The epoxy resin (A) is a thermosetting resin having an epoxy group, and preferably has an epoxy equivalent of 500 g/eq or less. The epoxy resin (A) may be liquid, solid, or semi-solid. The liquid in the present invention means that the softening point is less than 25° C. The solid means that the softening point is 60° C. or more. The semi-solid means that the softening point is between the softening point of the liquid and the softening point of the solid (25° C. or more and less than 60° C.). As the epoxy resin (A) used in the present invention, the softening point is preferably 100° C. or less from the viewpoint of obtaining a film adhesive that can reach low melt viscosity in a preferable temperature range (for example, 60 to 120° C.). Incidentally, in the present invention, the softening point is a value measured by the softening point test (ring and ball) method (measurement condition: in accordance with JIS-K7234:1986).

In the epoxy resin (A) used in the present invention, the epoxy equivalent is preferably from 150 to 450 g/eq from the viewpoint of increasing the crosslinking density of a thermally cured product. Note that, in the present invention, the epoxy equivalent refers to the number of grams of a resin containing 1 gram equivalent of epoxy group (g/eq).

The weight average molecular weight of the epoxy resin (A) is usually preferably less than 10000 and more preferably 5000 or less. The lower limit is not particularly limited, but is practically 300 or more.

The weight average molecular weight is a value obtained by GPC (Gel Permeation Chromatography) analysis (hereinafter, the same applies to other resins unless otherwise specified).

Examples of the skeleton of the epoxy resin (A) include a phenol novolac type, an orthocresol novolac type, a cresol novolac type, a dicyclopentadiene type, a biphenyl type, a fluorene bisphenol type, a triazine type, a naphthol type, a naphthalene diol type, a triphenylmethane type, a tetraphenyl type, a bisphenol A type, a bisphenol F type, a bisphenol AD type, a bisphenol S type, and a trimethylolmethane type. Among these skeletons, a triphenylmethane type, a bisphenol A type, a cresol novolac type, and an orthocresol novolac type are preferable from the viewpoint of being capable of obtaining a film adhesive having low resin crystallinity and good appearance.

The content of the epoxy resin (A) is preferably 3 to 70 parts by mass, preferably 5 to 50 parts by mass, and more preferably 8 to 30 parts by mass as well as preferably 8 to 20 parts by mass, based on 100 parts by mass of the total content of components constituting the film adhesive (specifically, components other than a solvent, i.e., a solid content) in the adhesive composition of the present invention.

### <Epoxy Resin Curing Agent (B)>

As the epoxy resin curing agent (B), optional curing agents such as amines, acid anhydrides, and polyhydric phenols can be used. In the present invention, a latent curing agent is preferably used from the viewpoint of having a low melt viscosity, and being capable of providing a film adhesive that exhibits curability at a high temperature exceeding a certain temperature, has rapid curability, and further has high storage stability that enables long-term storage at room temperature.

Examples of the latent curing agent include a dicyandiamide compound, an imidazole compound, a curing catalyst composite-based polyhydric phenol compound, a hydrazide compound, a boron trifluoride-amine complex, an amine imide compound, a polyamine salt, a modified product thereof, or those of a microcapsule type. These may be used singly, or in combination of two or more types thereof. Use of an imidazole compound is more preferable from the viewpoint of providing even better latency (properties of excellent stability at room temperature and exhibiting curability by heating) and providing a more rapid curing rate.

The content of the epoxy resin curing agent (B) in the adhesive composition may be set, if appropriate, according to the type and reaction form of the curing agent. For example, the content can be 0.5 to 100 parts by mass, may be 1 to 80 parts by mass or 2 to 50 parts by mass, and is also preferably 4 to 20 parts by mass based on 100 parts by mass of the epoxy resin (A). In addition, in the case of using an imidazole compound as the epoxy resin curing agent (B), the content of the imidazole compound is preferably from 0.5 to 10 parts by mass and more preferably from 2 to 9 parts by mass based on 100 parts by mass of the epoxy resin (A). Setting the content of the epoxy resin curing agent (B) to the preferable lower limit or more can further reduce the curing time. On the other hand, setting the content to the preferable upper limit or less can suppress excessive remaining of the curing agent in the film adhesive. As a result, moisture absorption by the remaining curing agent can be suppressed, and thus the reliability of the semiconductor device can be improved.

<Polymer component (C)>

The polymer component (C) has only to be a component that suppresses a film tack property at normal temperature (25° C.) (property that the film state is likely to change by even a little temperature change) and imparts sufficient adhesiveness and film formability (film forming property) when the film adhesive is formed. Examples thereof include a natural rubber, a butyl rubber, an isoprene rubber, a chloroprene rubber, an ethylene-vinyl acetate copolymer, an ethylene-(meth)acrylic acid copolymer, an ethylene-(meth)acrylic acid ester copolymer, a polybutadiene resin, a polycarbonate resin, a thermoplastic polyimide resin, polyamide resins such as 6-nylon and 6,6-nylon, a phenoxy resin, a (meth)acrylic resin, polyester resins such as polyethylene terephthalate and polybutylene terephthalate, a polyamideimide resin, a fluororesin, and a polyurethane resin. These polymer components (C) may be used singly, or in combination of two or more types thereof. As the polymer component (C), a phenoxy resin, a (meth)acrylic resin, or a polyurethane resin is preferable.

The polymer component (C) has a mass average molecular weight of 10000 or more. The upper limit is not particularly limited, but is practically 5000000 or less.

The mass average molecular weight of the polymer component (C) is a value determined by GPC (Gel Permeation Chromatography) in terms of polystyrene. Hereinafter, the value of the mass average molecular weight of the specific polymer component (C) has the same meaning.

The glass transition temperature (Tg) of the polymer component (C) is preferably less than 100° C., and more preferably less than 90° C. The lower limit is preferably 0° C. or more, and more preferably 10° C. or more.

The glass transition temperature of the polymer component (C) is a glass transition temperature measured by DSC at a temperature elevation rate of 0.1° C./min. Hereinafter, the value of the glass transition temperature of the specific polymer component (C) has the same meaning.

Note that, in the present invention, with regard to the epoxy resin (A) and a resin which can have an epoxy group such as phenoxy resin among the polymer component (C), a resin having an epoxy equivalent of 500 g/eq or less is classified into the epoxy resin (A) and a resin which does not correspond to the above resin is classified into the component (C).

### (Phenoxy Resin)

The phenoxy resin has a structure similar to that of the epoxy resin (A), and is thus preferable as the polymer component (C) from the viewpoint of good compatibility. Inclusion of the phenoxy resin can exert an excellent effect on adhesion performance.

The phenoxy resin can be obtained by a usual method. For example, the phenoxy resin can be obtained by a reaction of a bisphenol or biphenol compound with epihalohydrin such as epichlorohydrin, or a reaction of liquid epoxy resin with a bisphenol or biphenol compound.

The mass average molecular weight of the phenoxy resin is preferably 10000 or more and more preferably 10000 to 100,000.

Further, the amount of epoxy group remaining in a small amount in the phenoxy resin is an epoxy equivalent of preferably 5000 g/eq or more.

The glass transition temperature (Tg) of the phenoxy resin is preferably less than 100° C., and more preferably less than 90° C. The lower limit is preferably 0° C. or more, and more preferably 10° C. or more.

### ((Meth)Acrylic Resin)

The (meth)acrylic resin is not particularly limited, and a resin composed of a known (meth)acrylic copolymer can be widely used as a film component of the film adhesive.

Examples of the (meth)acrylic resin include poly(meth)acrylic acid esters and derivatives thereof. Examples thereof include copolymers containing, as a monomer component, 2-hydroxyethyl acrylate, 2-hydroxyethyl methacrylate, 2-hydroxypropyl acrylate, 2-hydroxypropyl methacrylate, acrylic acid, methacrylic acid, itaconic acid, glycidylmethacrylate, glycidylacrylate, and the like.

In addition, preferred is a copolymer using, as a monomer, a (meth)acrylic acid ester having a cyclic skeleton (e.g., a (meth)acrylic acid cycloalkyl ester, a (meth)acrylic acid benzyl ester, isobornyl (meth)acrylate, dicyclopentanyl (meth)acrylate, dicyclopentenyl (meth)acrylate, dicyclopentenyloxyethyl (meth)acrylate, imide(meth)acrylate).

Also preferred is a monomer component such as a (meth)acrylic acid alkyl ester having a C₁₋₁₈ alkyl (e.g., methyl (meth)acrylate, ethyl (meth)acrylate, propyl (meth)acrylate, butyl (meth)acrylate).

Also, these monomer components may be copolymerized with vinyl acetate, (meth)acrylonitrile, styrene, or the like.

Further, a (meth)acrylic resin having a hydroxy group is preferable because compatibility with the epoxy resin is favorable.

The mass average molecular weight of the (meth)acrylic copolymer is preferably 10,000 to 2,000,000, and more preferably 100,000 to 1,500,000. By adjusting the mass average molecular weight to a level within the preferable range, a tack property can be reduced and increase in the melt viscosity can also be suppressed.

The glass transition temperature of the (meth)acrylic copolymer is in a range of preferably −35° C. to 50° C., more preferably −10° C. to 50° C., still more preferably 0° C. to 40° C., and particularly preferably 0° C. to 30° C. By adjusting the glass transition temperature to a level within the preferable range, a tack property can be reduced and generation of voids between the semiconductor wafer and the film adhesive, and the like can be suppressed.

### <Polyurethane Resin>

The polyurethane resin is a polymer having a urethane (carbamic acid ester) bond in the main chain. The polyurethane resin has a constituent unit derived from a polyol and a constituent unit derived from a polyisocyanate, and may further have a constituent unit derived from a polycarboxylic acid. One kind of the polyurethane resin may be used singly, or two or more kinds thereof may be used in combination.

The Tg of the polyurethane resin is usually 100° C. or lower, preferably 60° C. or lower, more preferably 50° C. or lower, and also preferably 45° C. or lower.

The weight-average molecular weight of the polyurethane resin is not particularly limited, and a polyurethane resin having a weight-average molecular weight within a range of 5000 to 500000 is usually used.

The polyurethane resin can be synthesized by an ordinarily method, and can also be obtained from the market. Examples of a commercially available product that can be applied as the polyurethane resin include Dynaleo VA-9320M, Dynaleo VA-9310MF, or Dynaleo VA-9303MF (all manufactured by TOYOCHEM CO., LTD.).

The content of the polymer component (C) per 100 parts by mass of the epoxy resin (A) is preferably 1 to 40 parts by mass, more preferably 5 to 35 parts by mass, and even more preferably 10 to 30 parts by mass. The rigidity and flexibility of the thermally conductive film adhesive before curing can be controlled by adjusting the content to such a range. The state of the film becomes favorable (film tack property is reduced), and thus film brittleness can also be suppressed.

### <Polyhedral Alumina Filler (D)>

The polyhedral alumina filler (D) is inorganic powder containing alumina (aluminum oxide), and has a polyhedral shape. In the present invention, the “polyhedron” refers to a solid having a plurality of planes. The polyhedron only needs to have at least two planes, preferably has four or more planes, and more preferably has eight or more planes. The upper limit of the number of planes constituting the polyhedron is not particularly limited, but for example, about 20 is practical. The shape of the plane is not particularly limited, and examples thereof include a polygon (e.g., triangles, quadrangles, pentagons, hexagons). The polyhedron may have a curved surface in addition to a flat surface. Examples of the polyhedron include a plate-like shape, a columnar shape, a prismatic shape, a cylindrical shape, or a regular polyhedron. The polyhedral alumina filler (D) may contain a spherical alumina filler as long as the percentage of the spherical alumina filler to the total content of the components (A) to (E) is from about 1 to 50 vol %. That is, the polyhedral alumina filler (D) may contain a polyhedral alumina filler and a spherical alumina filler. In such a case, the polyhedral alumina filler and the spherical alumina filler are collectively referred to as a polyhedral alumina filler (D). The percentage of the spherical alumina filler contained in the polyhedral alumina filler (D) may be 40 vol % or less, 30 vol % or less, 10 vol % or less, or 5 vol % or less. The content of the spherical alumina filler contained in the polyhedral alumina filler (D) may be 80 mass % or less, 50 mass % or less, 30 mass %, 20 mass % or less, or 10 mass % or less based on the total amount of the polyhedral alumina filler (D). All the alumina fillers contained in the polyhedral alumina filler (D) may also be a polyhedral alumina filler(s). The preferred range of the average particle diameter of the polyhedral alumina filler (D) described later also corresponds to the average particle diameter of the spherical alumina filler.

The shape of the polyhedral alumina filler can be checked by observation using a scanning electron microscope (SEM), and when two or more planes can be found, the filler can be determined to be a “polyhedron”.

Use of the polyhedral alumina filler (D) makes it possible to increase the thermal conductivity, due to, for instance, an increase in the contact area between the fillers, even with the same filling amount as compared with the case of using a spherical alumina filler.

The average particle diameter (d50) of the polyhedral alumina filler (D) is not particularly limited, but is preferably 0.01 to 6.0 μm, preferably 0.01 to 5.0 μm, more preferably 0.1 to 4.0 μm, and still more preferably 0.3 to 3.5 μm from the viewpoint of making the film adhesive thinner. The average particle diameter (d50) is a so-called median diameter, and refers to a particle diameter at which the cumulative volume is 50% when the particle size distribution is measured by the laser diffraction scattering method and the total volume of the particles is defined as 100% in the cumulative distribution.

The polyhedral alumina filler (D) preferably has a plurality of different average particle diameters (d50), and more preferably has two different average particle diameters (d50), which may be used in combination. In this way, the content of the polyhedral alumina filler (D) in the adhesive layer can be further increased to improve the thermal conductivity.

The polyhedral alumina filler (D) having two different average particle diameters (d50) may be used in combination. In this case, for example, the average particle diameter of the polyhedral alumina filler (D1) having a relatively large average particle diameter (d50) is preferably from 1.0 to 8.0 μm, more preferably from 2.0 to 6.0 μm, still more preferably from 2.5 to 5.0 μm, and still more preferably from 2.5 to 4.0 μm. The average particle diameter (d50) of the polyhedral alumina filler (D2) having a relatively small average particle diameter (d50) is preferably from 0.10 to 0.80 μm, more preferably from 0.20 to 0.70 μm, still more preferably from 0.30 to 0.70 μm, and still more preferably from 0.35 to 0.65 μm.

Further, the ratio (D1/D2) (mass ratio) of the content of the polyhedral alumina filler (D1) having a relatively large average particle diameter (d50) to the content of the polyhedral alumina filler (D2) having a relatively small average particle diameter (d50) is preferably from 2 to 6 and more preferably from 3 to 5.

When a plurality of types of alumina fillers having different average particle sizes (d50) are used in combination as the polyhedral alumina filler (D), at least one type of alumina filler may be a spherical alumina filler. For example, instead of the polyhedral alumina filler having a relatively large average particle diameter (d50), a spherical alumina filler having a relatively large average particle diameter (d50) can be used. Instead of the polyhedral alumina filler having a relatively small average particle diameter (d50), a spherical alumina filler having a relatively small average particle diameter (d50) can also be used.

In the present invention, the term “spherical” does not correspond to the “polyhedron”, and means that the sphericity is from 0.5 to 1.0 (preferably from 0.6 to 1.0, more preferably from 0.7 to 1.0, and still more preferably from 0.8 to 1.0). The sphericity can be determined based on the area and the perimeter of the alumina filler observed with a scanning electron microscope. A specific procedure is as follows.

### (Sphericity of Alumina Filler)

A small amount of alumina filler is placed on a glass plate, and observed with a scanning electron microscope (model number: FlexSEM 1000II, manufactured by Hitachi High-Tech Co., Ltd.) at a magnification of 10000 times. Based on the observation image, the area and the perimeter of each particle of alumina filler are measured using particle analysis software, and the degree of unevenness of each particle of the inorganic filler was calculated by the following formulas (1) and (2).

$$Degree of unevenness of alumina filler = ( {perimeter}^{2} \times area ) \times 1 / 4 π \qquad ( 1 )$$

$$( 2 )$$

$$Sphericity of alumina filler = 1 / degree of unevenness of alumina filler$$

Ten alumina filler particles in the observation image are randomly observed, and the arithmetic mean value of the sphericity of 10 alumina filler particles is taken as the sphericity of the alumina filler.

The polyhedral alumina filler (D) may be subjected to surface treatment or surface modification. Examples of such surface treatment and surface modification include surface treatment and surface modification using a silane coupling agent, phosphoric acid or a phosphoric acid compound, and a surfactant. In addition to the items described in the present specification, for example, the descriptions of the silane coupling agent, the phosphoric acid or phosphoric acid compound, and the surfactant in the section of the thermally conductive filler in WO 2018/203527 or the section of the aluminum nitride filler in WO 2017/158994 can be applied.

The silane coupling agent used for surface treatment of the inorganic filler can be used without particular limitation.

In the present invention, the percentage of the polyhedral alumina filler (D) to the total content of the epoxy resin (A), the epoxy resin curing agent (B), the polymer component (C), the polyhedral alumina filler (D), and the silane coupling agent (E) is from 20 to 70 vol %. When the content ratio of the polyhedral alumina filler (D) may be the lower limit or more, desired thermal conductivity and melt viscosity can be imparted to the film adhesive, and an effect of dissipating heat from the semiconductor package can be obtained. In addition, when the content is the above upper limit or less, desired melt viscosity can be imparted to the film adhesive, and the strength of adhesion to an adherend can be enhanced.

The percentage of the polyhedral alumina filler (D) in the total content of the components (A) to (E) is preferably from 40 to 70 vol %, more preferably from 45 to 70 vol %, still more preferably from 50 to 70 vol %, still more preferably from 55 to 70 vol %, and still more preferably from 55 to 65 vol %.

The content (vol %) of the polyhedral alumina filler (D) can be calculated from the content mass and the specific gravity of each of the components (A) to (E).

### <Silane Coupling Agent (E)>

The adhesive composition of the present invention contains a silane coupling agent (E). In the present invention, the silane coupling agent (silane coupling agent already attached or adsorbed onto the surface of the polyhedral alumina filler (D) to be blended) used for the surface treatment of the polyhedral alumina filler (D) is not included in the silane coupling agent (E).

The silane coupling agent is a compound in which at least one hydrolyzable group such as an alkoxy group or an aryloxy group is bonded to a silicon atom. In addition to these groups, an alkyl group, an alkenyl group, or an aryl group may be bonded to the silicon atom. The alkyl group preferably has, as a substituent, an amino group, an alkoxy group, an epoxy group, or a (meth)acryloyloxy group, more preferably has, as a substituent, an amino group (preferably a phenylamino group), an alkoxy group (preferably a glycidyloxy group), or a (meth)acryloyloxy group, and particularly preferably has an amino group as a substituent.

Examples of the silane coupling agent include 2-(3,4-epoxycyclohexyl) ethyltrimethoxysilane, 3-glycidyloxypropyltrimethoxysilane, 3-glycidyloxypropyltriethoxysilane, 3-glycidyloxypropylmethyldimethoxysilane, 3-glycidyloxypropylmethyldiethoxysilane, dimethyldimethoxysilane, dimethyldiethoxysilane, methyltrimethoxysilane, methyltriethoxysilane, phenyltrimethoxysilane, phenyltriethoxysilane, 3-aminopropyltrimethoxysilane, N-phenyl-3-aminopropyltrimethoxysilane, 3-methacryloyloxypropylmethyldimethoxysilane, 3-methacryloyloxypropyltrimethoxysilane, 3-methacryloyloxypropylmethyldiethoxysilane, 3-methacryloyloxypropyltriethoxysilane, or vinyltrimethoxysilane.

The silane coupling agent (E) is blended so as to satisfy the blending multiple of the silane coupling agent as represented by (Formula I) described above.

### <Other Additives>

In addition to the epoxy resin (A), the epoxy resin curing agent (B), the polymer component (C), the polyhedral alumina filler (D), and the silane coupling agent (E), the adhesive composition of the present invention may further contain other additives such as an organic solvent (e.g., methyl ethyl ketone), an ion trapping agent (ion scavenger), a curing catalyst, a viscosity modifier, an antioxidant, a flame retardant, and/or a colorant as long as the effect of the present invention is not impaired. For example, “other additives” described in WO 2017/158994 can be included.

The proportion of the total content of the epoxy resin (A), the epoxy resin curing agent (B), the polymer component (C), the polyhedral alumina filler (D), and the silane coupling agent (E) in the adhesive composition of the present invention may be, for example, 60 mass % or larger, preferably 70 mass % or larger, more preferably 80 mass % or larger, and also 90 mass % or larger. Also, the proportion may be 100 mass %, and can be 95 mass % or less.

The adhesive composition of the present invention can be suitably used for obtaining the film adhesive of the present invention. However, the adhesive composition of the present invention is not limited to the film adhesive, and can also be suitably used for obtaining a liquid or paste adhesive, for example.

The adhesive composition of the present invention can be obtained by mixing the above components at a temperature at which the epoxy resin (A) is practically not cured. The order of mixing is not particularly limited. Resin components such as the epoxy resin (A) and the polymer component (C) may be mixed together with a solvent as necessary, and the polyhedral alumina filler (D), the epoxy resin curing agent (B), and the silane coupling agent (E) may then be mixed. In this case, the mixing in the presence of the epoxy resin curing agent (B) may be performed at a temperature at which the epoxy resin (A) is practically not cured, and the mixing of the resin components in the absence of the epoxy resin curing agent (B) may be performed at a higher temperature.

From the viewpoint of suppressing thermal curing of the epoxy resin (A), the adhesive composition of the present invention is preferably stored under a temperature condition at 10° C. or lower before use (before being formed into a film adhesive).

### [Thermally Conductive Film Adhesive]

The thermally conductive film adhesive of the present invention is a film adhesive obtained from the adhesive composition of the present invention. Thus, the thermally conductive film adhesive is produced by including an epoxy resin (A), an epoxy resin curing agent (B), a polymer component (C), a polyhedral alumina filler (D), and a silane coupling agent (E) as described above. Among the additives described as other additives in the adhesive composition of the present invention, the additives other than the organic solvent in addition to the above components may be contained.

More specifically, the thermally conductive film adhesive of the present invention is specified as follows:
a thermally conductive film adhesive including at least an epoxy resin (A), an epoxy resin curing agent (B), a polymer component (C), a polyhedral alumina filler (D), and a silane coupling agent (E),
wherein a percentage of the polyhedral alumina filler (D) to a total content of the epoxy resin (A), the epoxy resin curing agent (B), the polymer component (C), the polyhedral alumina filler (D), and the silane coupling agent (E) is from 20 to 70 vol %, and
wherein a blending multiple of the silane coupling agent as represented by the following (Formula I) is from 1.0 to 10:

Blending multiple of silane coupling agent=Blending amount(g) of silane coupling agent(E)/Required amount(g) of silane coupling agent(E) where (Formula I)

Required amount(g) of silane coupling agent(E)=[Blending amount(g) of polyhedral alumina filler(D)×Specific surface area(m²/g) of polyhedral alumina filler(D)]/Minimum coating area(m²/g) of silane coupling agent(E). (Formula II)

When the film adhesive of the present invention is formed using the adhesive composition containing an organic solvent, the solvent is usually removed from the adhesive composition by drying. Thus, the content of the solvent in the film adhesive of the present invention is 1000 ppm (ppm is on a mass basis) or less, and is usually 0.1 to 1000 ppm.

Here, the “film” in the present invention means a thin film having a thickness of 200 μm or less. The shape, size, and the like of the film are not particularly limited, and can be appropriately adjusted according to a use form.

The film adhesive of the present invention is in a state before curing, that is, in a state of B-stage.

As used herein, the film adhesive before curing refers to one in which the epoxy resin (A) is in a state before thermal curing. The film adhesive before thermal curing specifically means a film adhesive which is not exposed to a temperature condition at 25° C. or higher for 72 hours or longer after preparation of the film adhesive and is not exposed to a temperature condition at higher than 30° C. On the other hand, the film adhesive after curing refers to one in which the epoxy resin (A) is thermally cured. The above description is intended to clarify the characteristics of the adhesive composition of the present invention, and the film adhesive of the present invention is not limited to one that is not exposed to a temperature condition at 25° C. or higher for 72 hours or longer and is not exposed to a temperature condition at higher than 30° C.

The film adhesive of the present invention can be suitably used as a die attach film in a semiconductor production process.

In the film adhesive of the present invention, when the film adhesive before thermal curing is heated from 25° C. at a temperature elevation rate of 5° C./min, the melt viscosity at 120° C. is preferably in the range of 250 to 10000 Pa·s, more preferably in the range of 500 to 10000 Pa·s, still more preferably in the range of 600 to 9200 Pa·s, still more preferably in the range of 700 to 8000 Pa·s, and particularly preferably in the range of 2000 to 7200 Pa·s from the viewpoint of enhancing the die attachment performance.

The melt viscosity can be determined by the method described in Examples described later.

The melt viscosity can be appropriately controlled by the content of the polyhedral alumina filler (D), the particle diameter of the polyhedral alumina filler (D), and the type and content of coexisting compounds or resins such as the epoxy resin (A), the epoxy resin curing agent (B), the polymer component (C), and the silane coupling agent (E).

The film adhesive of the present invention has a thermal conductivity of preferably 1.0 W/m·K or larger, more preferably 1.0 to 5.0 W/m·K, still more preferably 1.5 to 4.5 W/m·K, still more preferably 1.7 to 4.5 W/m·K, and particularly preferably 2.3 to 4.2 W/m·K.

The thermal conductivity in the present invention is determined by the method described in Examples. That is, two silicon chips are bonded via a film adhesive to form a silicon chip/film adhesive/silicon chip structure, and the film adhesive is then thermally cured to form a simulated semiconductor package.

The thermal resistance of the film adhesive in the form of simulated semiconductor package is measured using DynTIM Tester (+T3Ster) manufactured by Mentor Graphics. As the measurement conditions of the thermal resistance, the measurement conditions described in Examples can be used.

Here, in general, the thermal conductivity can be calculated from the thickness and the thermal resistance value of a sample by using the following Equation (3):

$$Equation ( 3 )$$

$$λ ( W / m \cdot K , thermal conductivity ) = L ( m , sample thickness ) / R ( {m}^{2} \cdot K / W , sample thermal resistance ) .$$

In the present invention, the thermal resistance at each thickness is measured while the thickness of the film adhesive is set to 10 μm, 20 μm, or 50 μm; the obtained thermal resistance at each thicknesses is plotted against the thickness to draw an approximate straight line by a least squares method; and the thermal conductivity (thermal conductivity in a package form) is calculated as the reciprocal of the slope. In this way, it is possible to cancel the thermal resistance by the instrument (including the silicon chips disposed above and below the film adhesive) used for the measurement, and it is possible to accurately measure the thermal conductivity of the film adhesive itself.

The above measurement method allows for evaluation of the thermal conductivity of the film adhesive itself in a state closer to the actual use environment (mounting state).

The film adhesive of the present invention preferably has a die shear strength at 25° C. of 20 MPa or more. The die shear strength within the above range is preferable because the semiconductor chip can be reliably bonded to an adherend.

The die shear strength can be measured by the method described in Examples.

The film adhesive of the present invention has a thickness of preferably 1 to 80 μm, more preferably 1 to 50 μm, and still more preferably 1 to 20 μm.

The thickness of the film adhesive can be measured by a contact type linear gauge method (desk-top contact type thickness measurement apparatus).

For example, the film adhesive of the present invention can be formed by preparing the adhesive composition (varnish) of the present invention, applying the composition onto a release-treated substrate film, and drying the composition as necessary. The adhesive composition usually contains an organic solvent.

As the release-treated substrate film, any release-treated substrate film that functions as a cover film of the obtained film adhesive can be used, and a publicly known film can be appropriately employed. Examples thereof include release-treated polypropylene (PP), release-treated polyethylene (PE), or release-treated polyethylene terephthalate (PET).

A publicly known method can be appropriately employed as an application method, and examples thereof include methods using a roll knife coater, a gravure coater, a die coater, a reverse coater, and the like.

The drying may be performed by removing the organic solvent from the adhesive composition without curing the epoxy resin (A) to form a film adhesive, and can be performed, for example, by holding the composition at a temperature of 80 to 150° C. for 1 to 20 minutes.

The film adhesive of the present invention may be formed of the film adhesive of the present invention alone, or may have a form obtained by bonding a release-treated substrate film described above to at least one surface of the film adhesive. Further, a dicing die attach film may be formed integrally with the dicing film. The film adhesive of the present invention may be a form obtained by cutting the film into an appropriate size, or a form obtained by winding the film into a roll form.

From the viewpoint of suppressing curing of the epoxy resin (A), the film adhesive of the present invention is preferably stored under a temperature condition at 10° C. or lower before use (before curing).

### [Semiconductor Package and Producing Method Thereof]

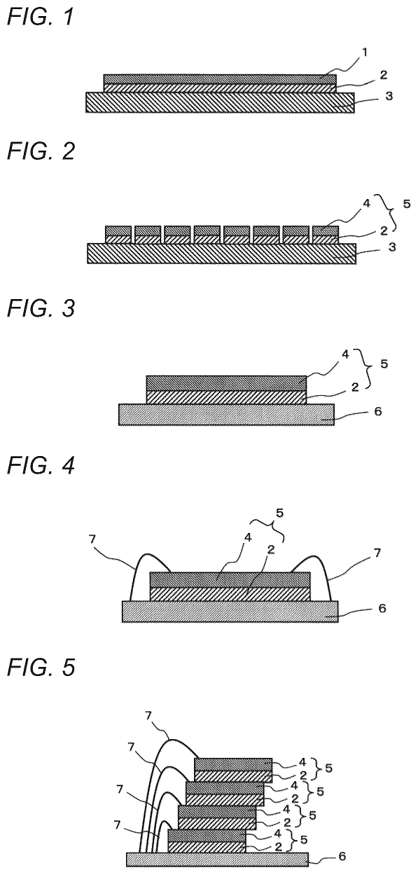

Then, preferred embodiments of a semiconductor package and a method of producing the same of the present invention will be described in detail with reference to the drawings. Note that, in the descriptions and drawings below, the same reference numerals are given to the same or corresponding components, and overlapping descriptions will be omitted. FIGS. 1 to 7 are schematic longitudinal cross-sectional views each illustrating a preferred embodiment of each step of a method of producing a semiconductor package of the present invention.

In the method of producing a semiconductor package of the present invention, as a first step, as illustrated in FIG. 1, the film adhesive 2 (die attach film 2) of the present invention is thermocompression bonded to the back surface of a semiconductor wafer 1 in which at least one semiconductor circuit is formed on a surface (that is, the back surface is a surface of the semiconductor wafer 1 on which the semiconductor circuit is not formed) to provide an adhesive layer (film adhesive 2), and then a dicing film 3 (dicing tape 3) is provided with this adhesive layer (film adhesive 2) interposed therebetween. In FIG. 1, the film adhesive 2 is illustrated smaller than the dicing film 3, but the sizes (areas) of both films are set, if appropriate, according to the purpose. For the condition of thermocompression bonding, thermocompression bonding is performed at a temperature at which the epoxy resin (A) is not thermally cured actually. Examples include the condition at a temperature of about 70° C. and a pressure of about 0.3 MPa.

As the semiconductor wafer 1, a semiconductor wafer where at least one semiconductor circuit is formed on the surface can be appropriately used. Examples thereof include a silicon wafer, a SiC wafer, a GaAs wafer, and a GaN wafer. In order to provide the film adhesive (die attach film) of the present invention on the back surface of the semiconductor wafer 1, for example, a publicly known apparatus such as a roll laminator or a manual laminator can be appropriately used.

In the above, the die attach film and the dicing film are separately attached. However, when the film adhesive of the present invention is in the form of a dicing die attach film, the film adhesive and the dicing film can be integrally bonded.

Next, as a second step, as illustrated in FIG. 2, the semiconductor wafer 1 and the adhesive layer (the die attach film 2) are integrally diced to give a semiconductor chip 5 with an adhesive layer on the dicing film 3, the semiconductor chip 5 with an adhesive layer including a semiconductor chip 4 obtained by dicing the semiconductor wafer and a piece of film adhesive 2 obtained by dicing the film adhesive 2. Further, an apparatus used for dicing is not particularly limited, and a common dicing apparatus can be used, if appropriate.

Next, as the third step, the semiconductor chip 5 with an adhesive layer is peeled off from the dicing film 3. At this time, if necessary, the dicing film may be cured with energy rays to reduce the adhesion strength. The peeling can be performed by picking up the semiconductor chip 5 with an adhesive layer. Then, as illustrated in FIG. 3, the semiconductor chip 5 with an adhesive layer and the circuit board 6 are thermocompression bonded via a piece of film adhesive 2 to mount the semiconductor chip 5 with an adhesive layer on the circuit board 6. As the circuit board 6, a substrate where a semiconductor circuit is formed on the surface can be used, if appropriate. Examples of such a substrate include a print circuit board (PCB), each lead frame, and a substrate where electronic components such as a resistive element and a capacitor are mounted on a surface of the substrate.

A method of mounting the semiconductor chip 5 with an adhesive layer on such a circuit board 6 is not particularly limited, and a conventional thermocompression bonding mounting method can be appropriately adopted.

Then, as a fourth step, the piece of film adhesive 2 is thermally cured. The temperature of the thermal curing is not particularly limited as long as the temperature is equal to or higher than a temperature at which thermal curing starts in the piece of film adhesive 2, and is adjusted, if appropriate, depending on the types of the epoxy resin (A), the polymer component (C), and the epoxy curing agent (B) used. For example, the temperature is preferably from 100 to 180° C. and more preferably from 140 to 180° C. from the viewpoint of curing in a shorter time. If the temperature is too high, the components in the piece of film adhesive 2 tend to be volatilized during the curing process. This is likely to cause foaming. The duration of this thermal curing treatment may be set, if appropriate, according to the heating temperature, and can be, for example, from 10 to 120 minutes.

In the method of producing a semiconductor package of the present invention, it is preferable that the circuit board 6 and the semiconductor chip 5 with an adhesive layer are connected via a bonding wire 7 as illustrated in FIG. 4. Such a connection method is not particularly limited, and a publicly known method, for example, a wire bonding method or a TAB (Tape Automated Bonding) method can be appropriately employed.

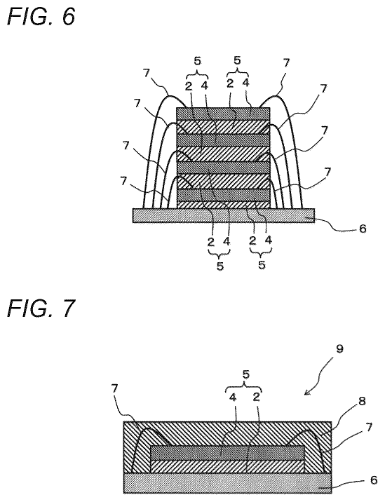

Further, a plurality of semiconductor chips 4 can be stacked by thermocompression bonding another semiconductor chip 4 to a surface of the mounted semiconductor chip 4, performing thermal curing, and then connecting the semiconductor chips 4 again to the circuit board 6 by wire bonding. Examples of the stacking method include a method of stacking the semiconductor chips in slightly different positions as illustrated in FIG. 5, and a method of stacking the semiconductor chips by increasing the thicknesses of the piece of film adhesive 2 of the second layer or later and thereby embedding the bonding wire 7 in each piece of film adhesive 2 as illustrated in FIG. 6.

In the method of producing a semiconductor package of the present invention, it is preferable to seal the circuit board 6 and the semiconductor chip 5 with an adhesive layer by using a sealing resin 8 as illustrated in FIG. 7. In this way, the semiconductor package 9 can be obtained. The sealing resin 8 is not particularly limited, and a publicly known sealing resin that can be used for the production of the semiconductor package can be used, if appropriate. In addition, a sealing method using the sealing resin 8 is not particularly limited, and a routinely conducted method can be employed.

The semiconductor package of the present invention is produced by the above-described method of producing a semiconductor package. At least one site disposed between a semiconductor chip and a circuit board or between semiconductor chips is bonded with a thermally cured product of the film adhesive of the present invention.

### EXAMPLES

Hereinafter, the present invention will be described in more detail based on Examples and Comparative Examples. However, the present invention is not limited to the following Examples.

In Examples and Comparative Examples, the room temperature means 25° C., MEK is methyl ethyl ketone, IPA is isopropyl alcohol, and PET is polyethylene terephthalate. “%” and “part” are on a mass basis unless otherwise specified.

### Example 1

In a 1000-ml separable flask, 56 parts by mass of triphenylmethane type epoxy resin (trade name: EPPN-501H, weight average molecular weight: 1000, softening point: 55° C., solid, epoxy equivalent: 167 g/eq, manufactured by Nippon Kayaku Co., Ltd.), 49 parts by mass of bisphenol A type epoxy resin (trade name: YD-128, weight average molecular weight: 400, softening point: 25° C. or less, liquid, epoxy equivalent: 190 g/eq, manufactured by NSCC Epoxy Manufacturing Co., Ltd.), 30 parts by mass of bisphenol A type phenoxy resin (trade name: YP-50, weight average molecular weight: 70000, Tg: 84° C., manufactured by NSCC Epoxy Manufacturing Co., Ltd.), and 67 parts by mass of MEK were heated with stirring at 110° C. for 2 hours, thus obtaining a resin varnish.

Subsequently, all of the resin varnish (202 parts by mass) was transferred to an 800-ml planetary mixer, and 205 parts by mass of polyhedral alumina filler (trade name: AA-3; average particle diameter (d50): 3.5 μm; specific surface area: 0.6 m²/g; manufactured by Sumitomo Chemical Co., Ltd.), 8.5 parts by mass of imidazole-type curing agent (trade name: 2PHZ-PW, manufactured by SHIKOKU KASEI HOLDINGS CORPORATION), and 3.0 parts by mass of silane coupling agent (3-glycidyloxytrimethoxysilane; trade name: KBM-403; silane coupling agent minimum coating area: 330 m²/g; manufactured by Shin-Etsu Chemical Co., Ltd.) were introduced to the mixer. The contents were then mixed with stirring for 1 hour at room temperature. Then, defoaming under vacuum was conducted, thus obtaining a mixed varnish (adhesive composition).

Thereafter, the resulting mixed varnish was applied onto a release-treated PET film having a thickness of 38 μm and then dried by heating (keeping at 130° C. for 10 minutes) to obtain a release film-attached film adhesive with a thickness of the film adhesive of 10 μm, 20 μm, or 50 μm.

### Example 2

An adhesive composition and a release film-attached film adhesive were obtained in the same manner as in Example 1 except that the amount of the polyhedral alumina filler blended was 319 parts by mass.

### Example 3

An adhesive composition and a release film-attached film adhesive were obtained in the same manner as in Example 1 except that the amount of the polyhedral alumina filler blended was 478 parts by mass.

### Example 4

An adhesive composition and a release film-attached film adhesive were obtained in the same manner as in Example 1 except that as a filler, 383 parts by mass of polyhedral alumina filler (trade name: AA-3; average particle diameter (d50): 3.5 μm; specific surface area: 0.6 m²/g; manufactured by Sumitomo Chemical Co., Ltd.) and 96 parts by mass of polyhedral alumina filler (trade name: AA-05; average particle diameter (d50): 0.58 μm; specific surface area: 3.2 m²/g; manufactured by Sumitomo Chemical Co., Ltd.) were used.

### Example 5

An adhesive composition and a release film-attached film adhesive were obtained in the same manner as in Example 1 except that the amount of silane coupling agent blended was 4.5 parts by mass and as a filler, 580 parts by mass of polyhedral alumina filler (trade name: AA-3; average particle diameter (d50): 3.5 μm; specific surface area: 0.6 m²/g; manufactured by Sumitomo Chemical Co., Ltd.) and 145 parts by mass of polyhedral alumina filler (trade name: AA-05; average particle diameter (d50): 0.58 μm; specific surface area: 3.2 m²/g; manufactured by Sumitomo Chemical Co., Ltd.) were used.

### Example 6

An adhesive composition and a release film-attached film adhesive were obtained in the same manner as in Example 1 except that the amount of silane coupling agent blended was 5.5 parts by mass and as a filler, 725 parts by mass of polyhedral alumina filler (trade name: AA-3; average particle diameter (d50): 3.5 μm; specific surface area: 0.6 m²/g; manufactured by Sumitomo Chemical Co., Ltd.) and 181 parts by mass of polyhedral alumina filler (trade name: AA-05; average particle diameter (d50): 0.58 μm; specific surface area: 3.2 m²/g; manufactured by Sumitomo Chemical Co., Ltd.) were used.

### Example 7

An adhesive composition and a release film-attached film adhesive were obtained in the same manner as in Example 4 except that 3.0 parts by mass of silane coupling agent (vinyltrimethoxysilane; trade name: KBM-1003; silane coupling agent minimum coating area: 515 m²/g; manufactured by Shin-Etsu Chemical Co., Ltd.) was used as the silane coupling agent.

### Example 8

An adhesive composition and a release film-attached film adhesive were obtained in the same manner as in Example 4 except that 3.0 parts by mass of silane coupling agent (3-aminopropyltrimethoxysilane; trade name: KBM-903; silane coupling agent minimum coating area: 353 m²/g; manufactured by Shin-Etsu Chemical Co., Ltd.) was used as the silane coupling agent.

### Example 9

An adhesive composition and a release film-attached film adhesive were obtained in the same manner as in Example 4 except that 3.0 parts by mass of silane coupling agent (3-glycidyloxypropylmethyldimethoxysilane; trade name: KBM-402; silane coupling agent minimum coating area: 354 m²/g; manufactured by Shin-Etsu Chemical Co., Ltd.) was used as the silane coupling agent.

### Example 10

An adhesive composition and a release film-attached film adhesive were obtained in the same manner as in Example 4 except that instead of the phenoxy resin, 120 parts by mass (in which 30 parts by mass of a urethane resin was used) of urethane resin solution (trade name: Dynaleo VA-9310MF; weight average molecular weight: 110000; Tg: 27° C.; storage elastic modulus: 289 MPa; solvent: MEK/IPA mixed solvent; manufactured by TOYOCHEM CO., LTD.) was blended.

### Example 11

An adhesive composition and a release film-attached film adhesive were obtained in the same manner as in Example 4 except that instead of the phenoxy resin, 30 parts by mass of acrylic resin (trade name: SG-280EK23; weight average molecular weight: 800000; Tg: −29° C.; storage elastic modulus: 6.5 MPa; manufactured by Nagase ChemteX Corporation) was blended, and 90 parts by mass of cyclohexanone was blended.

### Example 12

An adhesive composition and a release film-attached film adhesive were obtained in the same manner as in Example 4 except that as a filler, 383 parts by mass of polyhedral alumina filler (trade name: AA-3; average particle diameter (d50): 3.5 μm; specific surface area: 0.6 m²/g; manufactured by Sumitomo Chemical Co., Ltd.) and 96 parts by mass of spherical alumina filler (trade name: AO502; average particle diameter (d50): 0.2 μm; specific surface area: 8.0 m²/g; sphericity: 0.99; manufactured by Admatechs) were blended, and the amount of silane coupling agent blended was 5.0 parts by mass. In Example 12, the percentage (vol %) of the spherical alumina filler to the total content of the epoxy resin, the epoxy resin curing agent, the polymer component, the silane coupling agent, and the inorganic filler was 10 vol %.

### Example 13

An adhesive composition and a release film-attached film adhesive were obtained in the same manner as in Example 4 except that as a filler, 383 parts by mass of spherical alumina filler (trade name: AZ2-75; average particle diameter (d50): 3.0 μm; specific surface area: 1.3 m²/g; sphericity: 0.99; manufactured by NIPPON STEEL Chemical & Material Co., Ltd.) and 96 parts by mass of polyhedral alumina filler (trade name: AA-05; average particle diameter (d50): 0.58 μm; specific surface area: 3.2 m²/g; manufactured by Sumitomo Chemical Co., Ltd.) were blended, and the amount of silane coupling agent blended was 5.0 parts by mass. In Example 13, the percentage (vol %) of the spherical alumina filler to the total content of the epoxy resin, the epoxy resin curing agent, the polymer component, the silane coupling agent, and the inorganic filler was 40 vol %.

### Comparative Example 1

An adhesive composition and a release film-attached film adhesive were obtained in the same manner as in Example 3 except that the amount of polyhedral alumina filler blended was 470 parts by mass and the amount of silane coupling agent blended was 0.4 parts by mass.

### Comparative Example 2

An adhesive composition and a release film-attached film adhesive were obtained in the same manner as in Example 4 except that as a filler, 375 parts by mass of polyhedral alumina filler (trade name: AA-3; average particle diameter (d50): 3.5 μm; specific surface area: 0.6 m²/g; manufactured by Sumitomo Chemical Co., Ltd.) and 94 parts by mass of polyhedral alumina filler (trade name: AA-05; average particle diameter (d50): 0.58 μm; specific surface area: 3.2 m²/g; manufactured by Sumitomo Chemical Co., Ltd.) were blended and no silane coupling agent was used.

### Comparative Example 3

An adhesive composition and a release film-attached film adhesive were obtained in the same manner as in Example 5 except that as a filler, 568 parts by mass of polyhedral alumina filler (trade name: AA-3; average particle diameter (d50): 3.5 μm; specific surface area: 0.6 m²/g; manufactured by Sumitomo Chemical Co., Ltd.) and 142 parts by mass of polyhedral alumina filler (trade name: AA-05; average particle diameter (d50): 0.58 μm; specific surface area: 3.2 m²/g; manufactured by Sumitomo Chemical Co., Ltd.) were blended and the amount of silane coupling agent blended was 1.2 parts by mass.

### Comparative Example 4

An adhesive composition and a release film-attached film adhesive were obtained in the same manner as in Example 8 except that as a filler, 428 parts by mass of polyhedral alumina filler (trade name: AA-3; average particle diameter (d50): 3.5 μm; specific surface area: 0.6 m²/g; manufactured by Sumitomo Chemical Co., Ltd.) and 107 parts by mass of polyhedral alumina filler (trade name: AA-05; average particle diameter (d50): 0.58 μm; specific surface area: 3.2 m²/g; manufactured by Sumitomo Chemical Co., Ltd.) were blended and the amount of silane coupling agent blended was 20.0 parts by mass.

### Comparative Example 5

An adhesive composition and a release film-attached film adhesive were obtained in the same manner as in Example 8 except that as a filler, 1160 parts by mass of polyhedral alumina filler (trade name: AA-3; average particle diameter (d50): 3.5 μm; specific surface area: 0.6 m²/g; manufactured by Sumitomo Chemical Co., Ltd.) and 290 parts by mass of polyhedral alumina filler (trade name: AA-05; average particle diameter (d50): 0.58 μm; specific surface area: 3.2 m²/g; manufactured by Sumitomo Chemical Co., Ltd.) were blended and the amount of silane coupling agent used was 4.5 parts by mass.

### Comparative Example 6

An adhesive composition and a release film-attached film adhesive were obtained in the same manner as in Example 4 except that as a filler, 377 parts by mass of polyhedral alumina filler (trade name: AA-3; average particle diameter (d50): 3.5 μm; specific surface area: 0.6 m²/g; manufactured by Sumitomo Chemical Co., Ltd.) and 94 parts by mass of polyhedral alumina filler (trade name: AA-05; average particle diameter (d50): 0.58 μm; specific surface area: 3.2 m²/g; manufactured by Sumitomo Chemical Co., Ltd.) were blended and the amount of silane coupling agent blended was 0.8 parts by mass.

### Reference Example 1

An adhesive composition and a release film-attached film adhesive were obtained in the same manner as in Example 4 except that as a filler, 378 parts by mass of spherical alumina filler (trade name: AZ2-75; average particle diameter (d50): 3.0 μm; specific surface area: 1.3 m²/g; sphericity: 0.99; manufactured by NIPPON STEEL Chemical & Material Co., Ltd.) and 95 parts by mass of spherical alumina filler (trade name: ASFP-05S; average particle diameter (d50): 0.6 μm; specific surface area: 3.6 m²/g; sphericity: 0.99; manufactured by Denka Company Limited) were used, and the amount of silane coupling agent blended was 1.3 parts by mass.

### Reference Example 2

An adhesive composition and a release film-attached film adhesive were obtained in the same manner as in Example 5 except that as a filler, 570 parts by mass of spherical alumina filler (trade name: AZ2-75; average particle diameter (d50): 3.0 μm; specific surface area: 1.3 m²/g; sphericity: 0.99; manufactured by NIPPON STEEL Chemical & Material Co., Ltd.) and 143 parts by mass of spherical alumina filler (trade name: ASFP-05S; average particle diameter (d50): 0.6 μm; specific surface area: 3.6 m²/g; sphericity: 0.99; manufactured by Denka Company Limited) were used, and the amount of silane coupling agent blended was 2.0 parts by mass.

### Reference Example 3

An adhesive composition and a release film-attached film adhesive were obtained in the same manner as in Example 6 except that as a filler, 708 parts by mass of spherical alumina filler (trade name: AZ2-75; average particle diameter (d50): 3.0 μm; specific surface area: 1.3 m²/g; sphericity: 0.99; manufactured by NIPPON STEEL Chemical & Material Co., Ltd.) and 177 parts by mass of spherical alumina filler (trade name: ASFP-05S; average particle diameter (d50): 0.6 μm; specific surface area: 3.6 m²/g; sphericity: 0.99; manufactured by Denka Company Limited) were used, and the amount of silane coupling agent blended was 2.4 parts by mass.

### Reference Example 4

An adhesive composition and a release film-attached film adhesive were obtained in the same manner as in Example 1 except that as a filler, 201 parts by mass of polyhedral alumina filler (trade name: AA-3; average particle diameter (d50): 3.5 μm; specific surface area: 0.6 m²/g; manufactured by Sumitomo Chemical Co., Ltd.) was used and the amount of silane coupling agent blended was 0.2 parts by mass.

### Reference Example 5

An adhesive composition and a release film-attached film adhesive were obtained in the same manner as in Reference Example 4 except that as a filler, 202 parts by mass of spherical alumina filler (trade name: AZ2-75; average particle diameter (d50): 3.0 μm; specific surface area: 1.3 m²/g; sphericity: 0.99; manufactured by NIPPON STEEL Chemical & Material Co., Ltd.) was used, and the amount of silane coupling agent blended was 0.4 parts by mass.

Tables 1 to 3 show the compositions of the film adhesives prepared in the respective Examples, Comparative Examples, or Reference Examples. An empty cell means that a corresponding component is not contained.

The “Inorganic filler content” shown in Tables 1 to 3 indicates the percentage (vol %) of the inorganic filler based on the total content of the epoxy resin, the epoxy resin curing agent, the polymer component, the silane coupling agent, and the inorganic filler.

### Test Example

In each of Examples, Comparative Examples, or Reference Examples, the specific surface area of the inorganic filler was measured, the melt viscosity of the film adhesive at 120° C. was measured, the bulk thermal conductivity was measured, the die shear strength was measured, the package assembly was evaluated, and the thermal conductivity (in a package form) was evaluated as each described below.

### (Measurement of Specific Surface Area of Inorganic Filler)

The specific surface area of the inorganic filler used in each of Examples, Comparative Examples, or Reference Examples was measured by the BET method according to JIS Z 8830:2013 (ISO 9277:2010) under the following conditions.
Measuring instrument: 4-connected specific surface area/pore distribution analyzer NOVA-TOUCH type (manufactured by Quantachrome Instruments)
Gas used: Nitrogen gas
Refrigerant (temperature): liquid nitrogen (77.35 K)
Pretreatment conditions: 110° C., vacuum degassing for 6 hours or longer
Measurement relative pressure: 0.05<P/P₀<0.3

### (Measurement of Melt Viscosity)

Squares having a size of length 5.0 cm×width 5.0 cm were cut out from the 10-μm film adhesive obtained in each of Examples, Comparative Examples, or Reference Examples. After the release film had been peeled off, the film adhesives were stacked onto each other and bonded on a stage at 70° C. by a hand roller. Thus, a test piece having a thickness of approximately 1.0 mm was obtained. A change in viscosity resistance in a temperature range of 20 to 250° C. at a temperature elevation rate of 5° C./min was measured for this test piece by using a rheometer (RS6000 (trade name), manufactured by Haake). The melt viscosities at 120° C. (Pa·s) were each calculated from the obtained temperature-viscosity resistance curve.

### (Measurement of Bulk Thermal Conductivity)

This test is a test for evaluating thermal conductivity of each film adhesive alone.

The film adhesive having a thickness of 10 μm as obtained in each of Examples, Comparative Examples, or Reference Examples was cut into square pieces having a side of 50 mm or more, and the cut square pieces (film adhesive) were laminated so that the thickness was 5 mm or more, thus obtaining a laminate. The resulting laminate was placed on a disk-shaped mold with a diameter of 50 mm and a thickness 5 mm, heated at a temperature of 150° C. and a pressure of 2 MPa for 10 minutes by using a compression molding machine, and then taken out. The laminate was further heated in a dryer at a temperature of 180° C. for 1 hour to thermally cure the film adhesive. Thus, a disk-shaped test piece having a diameter of 50 mm and a thickness of 5 mm was obtained.

The thermal conductivity (W/(m-K)) was measured for this test piece by using a thermal conductivity measurement apparatus (trade name: HC-110, manufacture by Eko Instruments Co., Ltd) according to the heat flow meter method (in accordance with JIS A 1412:2016).

In this test, the epoxy resin was thermally cured under the high temperature condition in order to completely cure the epoxy resin.

### (Evaluation of Die Shear Strength)

The 10-μm release film-attached film adhesive obtained in each Example, Comparative Example, or Reference Example was first bonded to one surface of a dummy silicon wafer (size: 8 inch, thickness: 365 μm) by using a manual laminator (trade name: FM-114, manufactured by Technovision, Inc.) at a temperature of 70° C. and a pressure of 0.3 MPa. Thereafter, the release film was peeled off from the film adhesive. Then, a dicing tape (trade name: K-13, manufactured by Furukawa Electric Co., Ltd.) and a dicing frame (trade name: DTF2-8-1H001, manufactured by DISCO Corporation) were bonded on a surface of the film adhesive opposite to the dummy silicon wafer, by using the same manual laminator under conditions at room temperature and a pressure of 0.3 MPa. Then, dicing was performed from the dummy silicon wafer side to form squares each having a size of 2 mm×2 mm by using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation) to prepare a dummy chip (semiconductor chip) with a film adhesive piece (adhesive layer) on the dicing film.

In addition, a dicing tape (trade name: K-8, manufactured by Furukawa Electric Co., Ltd.) and a dicing frame (trade name: DTF2-8-1H001, manufactured by DISCO Corporation) were bonded on a surface opposite to the dummy silicon wafer (size: 8 inches; thickness: 365 μm) mounting surface side, by using the manual laminator under conditions at room temperature and a pressure of 0.3 MPa. Next, dicing was performed from the silicon wafer side to form squares each having a size of 12 mm×12 mm by using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation), thus obtaining diced silicon chips on the dicing film.

Next, the film adhesive-attached dummy chip was picked up from the dicing tape by using a die bonder (trade name: DB-800, manufactured by Hitachi High-Tech Corporation). Then, the film adhesive side of the film adhesive-attached dummy chip was thermocompression bonded to the mounting surface side (surface with irregularities) of the silicon chip with a size of 12 mm×12 mm under conditions at a temperature of 120° C. and a pressure of 0.5 MPa (load: 200 gf) for 1.0 seconds. At this time, two film adhesive-attached dummy chips having a size of 2 mm×2 mm were arranged apart from each other on the mounting surface side of the silicon chip having a size of 12 mm×12 mm. In this way, a sample was obtained in which two film adhesive-attached dummy chips were mounted on one 12 mm×12 mm silicon chip. Four of these samples were prepared for each of Examples, Comparative Examples, or Reference Examples. Each sample was placed in a dryer and heated at a temperature of 120° C. for 2 hours to thermally cure the film adhesive. In this test, from the viewpoint of suppressing generation of voids during the thermal curing step, thermal curing was performed under conditions at a lower temperature and a longer time than those in the bulk thermal curing test.

After that, the die shear strength of the film adhesive-attached dummy chip against the silicon surface was measured using a bond tester (trade name: 4000 Universal Bond Tester, DAGE). The die shear strength was measured for eight film adhesive-attached dummy chips, averaged (average die shear strength), and evaluated according to the following criteria.

### Evaluation Criteria

AA: Average die shear strength is 20 MPa or more, and die shear strengths of all 8 film adhesive-attached dummy chips are 20 MPa or more.
A: Average die shear strength is 20 MPa or more, but the number of film adhesive-attached dummy chips having a die shear strength of 20 MPa or more is from 5 to 7.
B: Average die shear strength is less than 20 MPa.

### (Package Assembly Test)

This test is a test in which the assembly of semiconductor package is simulated by bonding the film adhesive-attached dummy chip to a silicon chip via the film adhesive, and the package assembly is evaluated in terms of a void(s) at the interface between the film adhesive and the silicon chip (substrate) as an index.

The 10-μm thick release film-attached film adhesive obtained in each of Examples, Comparative Examples, or Reference Examples was first bonded to one surface of a dummy silicon wafer (size: 8 inch, thickness: 365 μm) by using a manual laminator (trade name: FM-114, manufactured by Technovision, Inc.) at a temperature of 70° C. and a pressure of 0.3 MPa. Thereafter, the release film was peeled off from the film adhesive. Then, a dicing tape (trade name: K-13, manufactured by Furukawa Electric Co., Ltd.) and a dicing frame (trade name: DTF2-8-1H001, manufactured by DISCO Corporation) were bonded on a surface of the film adhesive opposite to the dummy silicon wafer side, by using the same manual laminator at room temperature and a pressure of 0.3 MPa. Then, dicing was performed from the dummy silicon wafer side to form squares each having a size of 10 mm×10 mm by using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation) to prepare a diced film adhesive-attached dummy chip on the dicing film.

In addition, a dicing tape (trade name: K-8, manufactured by Furukawa Electric Co., Ltd.) and a dicing frame (trade name: DTF2-8-1H001, manufactured by DISCO Corporation) were bonded on a surface of the film adhesive opposite to the dummy silicon wafer (size: 8 inches; thickness: 365 μm) mounting surface side, by using the manual laminator under conditions at room temperature and a pressure of 0.3 MPa. Next, dicing was performed from the silicon wafer side to form squares each having a size of 12 mm×12 mm by using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation), thus obtaining diced silicon chips on the dicing film.

Next, the film adhesive-attached dummy chip was picked up from the dicing tape by using a die bonder (trade name: DB-800, manufactured by Hitachi High-Tech Corporation). Then, the film adhesive side of the film adhesive-attached dummy chip was thermocompression bonded to the mounting surface side of the silicon chip with a size of 12 mm×12 mm under conditions at a temperature of 120° C. and a pressure of 1.0 MPa (load: 1000 gf) for 1.5 seconds. At this time, a film adhesive-attached dummy chip having a size of 10 mm×10 mm was arranged at the center of the mounting surface of a silicon chip having a size of 12 mm×12 mm. This was placed in a dryer and heated at a temperature of 120° C. for 2 hours to thermally cure the film adhesive. In this test, from the viewpoint of suppressing generation of voids during the thermal curing step, thermal curing was performed under conditions at a lower temperature and a longer time than those in the bulk thermal curing test. This resulted in a simulated semiconductor package in which a dummy chip and a silicon chip were laminated with a film adhesive interposed therebetween.

The resulting simulated semiconductor package thus obtained was observed for the presence or absence of voids at the interface between the film adhesive and the silicon chip mounting surface by using a Scanning Acoustic Tomograph (SAT) (FS 300111 (trade name) manufactured by Hitachi Power Solutions). The observation was performed using a probe having a frequency of 100 MHz or a probe having a frequency of 50 MHz. Five simulated semiconductor packages were observed and evaluated based on the following evaluation criteria. Smaller voids can be observed with a probe having a frequency of 100 MHz than with a probe having a frequency of 50 MHz. In this test, the evaluation rank “A” is an acceptable level.

### Evaluation Criteria

AA: No void is observed in all of the 5 simulated semiconductor packages when observed using a probe with a frequency of 100 MHz.
A: Although the above standard “AA” is not satisfied, no void is observed in all of the 5 simulated semiconductor packages when observed using a probe with a frequency of 50 MHz.
B: Some voids are observed in 1 to 4 of the simulated semiconductor packages when observed using a probe with a frequency of 50 MHz.
C: Some voids are observed in all of the 5 simulated semiconductor packages when observed using a probe with a frequency of 50 MHz.

### (Test for Thermal Conductivity in Package Form)

This test is a test for evaluating thermal conductivity of a film adhesive in a form of a simulated semiconductor package (silicon chip (dummy chip described above)/film adhesive/silicon chip) in which the film adhesive-attached dummy chip is bonded via the film adhesive to a silicon chip so that the film adhesive was sandwiched between two silicon chips.

Three types of release film-attached film adhesives with a thicknesses of 10 μm, 20 μm, or 50 μm as obtained in each of Examples, Comparative Examples, or Reference Examples were each made into the form of a simulated semiconductor package by the same procedure as in the package assembly test. For these simulated semiconductor packages, the thermal resistance of the film adhesive in each simulated semiconductor package was measured using DynTIM Tester (+T3Ster) manufactured by Mentor Graphics under the following conditions.
Atmosphere: in the atmosphere
Measurement direction: thickness direction
Measurement temperature: 23° C. (low temperature side base temperature)
Temperature elevation: 5 to 15° C. (temperature difference between upper and lower surfaces of sample)

In this test, the obtained thermal resistance value was plotted with respect to the thickness, and the thermal conductivity in a package form was calculated as the reciprocal of the slope. In this way, the thermal resistance by the instrument (including the semiconductor and silicon chips disposed above and below the film adhesive) used for the measurement was canceled, and the thermal conductivity of the film adhesive itself was measured.

The resulting thermal conductivity in a package form was evaluated based on the following evaluation criteria.

### Evaluation Criteria

AAA: Thermal conductivity in a package form is 2.5 W/m·K or more
AA: Thermal conductivity in a package form is 1.5 W/m·K or more and less than 2.5 W/m·K
A: Thermal conductivity in a package form is 1.0 W/m·K or more and less than 1.5 W/m·K
B: Thermal conductivity in a package form is 0.5 W/m·K or more and less than 1.0 W/m·K
C: Thermal conductivity in a package form is less than 0.5 W/m·K

The above respective test results are shown in the following Tables.

TABLE 1

| | | | Example | | | | | |
|---|---|---|---|---|---|---|---|---|
| | | | 1 | 2 | 3 | 4 | 5 | 6 |
| Film | Epoxy | EPPN-501H (Triphenylmethane-type epoxy resin) | 56 | 56 | 56 | 56 | 56 | 56 |
| adhesive | resin | YD-128 (Liquid Bis A-type epoxy resin) | 49 | 49 | 49 | 49 | 49 | 49 |
| composition | Polymer | YP-50 (Bis A-type phenoxy resin) | 30 | 30 | 30 | 30 | 30 | 30 |
| (parts by | component | VA-9310MF (Urethane resin) | | | | | | |
| mass) | | SG-280EK23 (Acrylic resin) | | | | | | |
| | Inorganic | AA-3 (Polyhedral alumina filler; | 205 | 319 | 478 | 383 | 580 | 725 |
| | filler | average particle diameter: 3.5 μm) | | | | | | |
| | | AZ2-75 (Spherical alumina filler; | | | | | | |
| | | average particle shape: 3.0 μm) | | | | | | |
| | | AO502 (Spherical alumina filler;: | | | | | | |
| | | average particle shape: 0.2 μm) | | | | | | |
| | | AA-05 (Polyhedral alumina filler; | | | | 96 | 145 | 181 |
| | | average particle diameter: 0.58 μm) | | | | | | |
| | Silane | KBM-403 (3-Glycidyloxytrimethoxysilane) | 3.0 | 3.0 | 3.0 | 3.0 | 4.5 | 5.5 |
| | coupling | KBM-1003 (Vinyltrimethoxysilane) | | | | | | |
| | agent | KBM-903 (3-Aminopropyltrimethoxysilane) | | | | | | |
| | | KBM-402 (3-Glycidyloxypropylmethyldimethoxysilane) | | | | | | |
| | Curing agent | 2PHZ-PW (imidazole-type curing agent) | 8.5 | 8.5 | 8.5 | 8.5 | 8.5 | 8.5 |

| | | | | | | |
|---|---|---|---|---|---|---|
| Total solid content (parts by mass) | 351 | 465 | 624 | 624 | 872 | 1054 |
| Inorganic filler loading amount (vol %) | 30.0 | 40.0 | 50.0 | 50.0 | 60.0 | 65.0 |
| Required amount (g) of silane coupling agent | 0.37 | 0.58 | 0.87 | 1.62 | 2.46 | 3.08 |
| Blending multiple of silane coupling agent | 8.0 | 5.2 | 3.5 | 1.8 | 1.8 | 1.8 |

| | | | | | | |
|---|---|---|---|---|---|---|
| Melt viscosity at 120° C. (Pa · s) | 300 | 540 | 800 | 730 | 2350 | 6750 |
| Bulk thermal conductivity (W/m · K) | 1.2 | 1.6 | 2.0 | 2.3 | 3.2 | 4.0 |
| Die shear strength evaluation | AA | AA | AA | AA | A | A |
| Package assembly evaluation | AA | AA | AA | AA | AA | AA |
| Thermal conductivity (W/m · K) in package form | 1.1 | 1.4 | 1.8 | 2.1 | 3.0 | 3.9 |
| Evaluation of thermal conductivity in package form | A | A | AA | AA | AAA | AAA |

| | | | Example | | | |
|---|---|---|---|---|---|---|
| | | | 7 | 8 | 9 | 10 |
| Film | Epoxy | EPPN-501H (Triphenylmethane-type epoxy resin) | 56 | 56 | 56 | 56 |
| adhesive | resin | YD-128 (Liquid Bis A-type epoxy resin) | 49 | 49 | 49 | 49 |
| composition | Polymer | YP-50 (Bis A-type phenoxy resin) | 30 | 30 | 30 | |
| (parts by | component | VA-9310MF (Urethane resin) | | | | 30 |
| mass) | | SG-280EK23 (Acrylic resin) | | | | |
| | Inorganic | AA-3 (Polyhedral alumina filler; | 383 | 383 | 383 | 383 |
| | filler | average particle diameter: 3.5 μm) | | | | |
| | | AZ2-75 (Spherical alumina filler; | | | | |
| | | average particle shape: 3.0 μm) | | | | |
| | | AO502 (Spherical alumina filler;: | | | | |
| | | average particle shape: 0.2 μm) | | | | |
| | | AA-05 (Polyhedral alumina filler; | 96 | 96 | 96 | 96 |
| | | average particle diameter: 0.58 μm) | | | | |
| | Silane | KBM-403 (3-Glycidyloxytrimethoxysilane) | | | | 3.0 |
| | coupling | KBM-1003 (Vinyltrimethoxysilane) | 3.0 | | | |
| | agent | KBM-903 (3-Aminopropyltrimethoxysilane) | | 3.0 | | |
| | | KBM-402 (3-Glycidyloxypropylmethyldimethoxysilane) | | | 3.0 | |
| | Curing agent | 2PHZ-PW (imidazole-type curing agent) | 8.5 | 8.5 | 8.5 | 8.5 |

| | | | | |
|---|---|---|---|---|
| Total solid content (parts by mass) | 624 | 624 | 624 | 624 |
| Inorganic filler loading amount (vol %) | 50.0 | 50.0 | 50.0 | 50.0 |
| Required amount (g) of silane coupling agent | 1.04 | 1.52 | 1.51 | 1.62 |
| Blending multiple of silane coupling agent | 2.9 | 2.0 | 2.0 | 1.8 |

| | | | | |
|---|---|---|---|---|
| Melt viscosity at 120° C. (Pa · s) | 710 | 680 | 735 | 1340 |
| Bulk thermal conductivity (W/m · K) | 2.3 | 2.5 | 2.3 | 2.2 |
| Die shear strength evaluation | AA | AA | AA | A |
| Package assembly evaluation | AA | AA | AA | AA |
| Thermal conductivity (W/m · K) in package form | 2.1 | 2.5 | 2.1 | 2.1 |
| Evaluation of thermal conductivity in package form | AA | AAA | AA | AA |

| | | | Example | | |
|---|---|---|---|---|---|
| | | | 11 | 12 | 13 |
| Film | Epoxy | EPPN-501H (Triphenylmethane-type epoxy resin) | 56 | 56 | 56 |
| adhesive | resin | YD-128 (Liquid Bis A-type epoxy resin) | 49 | 49 | 49 |
| composition | Polymer | YP-50 (Bis A-type phenoxy resin) | | 30 | 30 |
| (parts by | component | VA-9310MF (Urethane resin) | | | |
| mass) | | SG-280EK23 (Acrylic resin) | 30 | | |
| | Inorganic | AA-3 (Polyhedral alumina filler; | 383 | 383 | |
| | filler | average particle diameter: 3.5 μm) | | | |
| | | AZ2-75 (Spherical alumina filler; | | | 383 |
| | | average particle shape: 3.0 μm) | | | |
| | | AO502 (Spherical alumina filler;: | | 96 | |
| | | average particle shape: 0.2 μm) | | | |
| | | AA-05 (Polyhedral alumina filler; | 96 | | 96 |
| | | average particle diameter: 0.58 μm) | | | |
| | Silane | KBM-403 (3-Glycidyloxytrimethoxysilane) | 3.0 | 5.0 | 5.0 |
| | coupling | KBM-1003 (Vinyltrimethoxysilane) | | | |
| | agent | KBM-903 (3-Aminopropyltrimethoxysilane) | | | |
| | | KBM-402 (3-Glycidyloxypropylmethyldimethoxysilane) | | | |
| | Curing agent | 2PHZ-PW (imidazole-type curing agent) | 8.5 | 8.5 | 8.5 |

| | | | |
|---|---|---|---|
| Total solid content (parts by mass) | 624 | 626 | 626 |
| Inorganic filler loading amount (vol %) | 50.0 | 49.6 | 49.6 |
| Required amount (g) of silane coupling agent | 1.62 | 3.02 | 2.44 |
| Blending multiple of silane coupling agent | 1.8 | 1.7 | 2.1 |

| | | | |
|---|---|---|---|
| Melt viscosity at 120° C. (Pa · s) | 2120 | 750 | 780 |
| Bulk thermal conductivity (W/m · K) | 2.3 | 2.1 | 2.1 |
| Die shear strength evaluation | A | AA | AA |
| Package assembly evaluation | AA | AA | AA |
| Thermal conductivity (W/m · K) in package form | 2.2 | 2.0 | 2.1 |
| Evaluation of thermal conductivity in package form | AA | AA | AA |

TABLE 2

| | | | Reference Example | | | | |
|---|---|---|---|---|---|---|---|
| | | | 1 | 2 | 3 | 4 | 5 |
| Film | Epoxy resin | EPPN-501 H (Triphenylmethane-type epoxy resin) | 56 | 56 | 56 | 56 | 56 |
| adhesive | | YD-128 (liquid Bis A-type epoxy resin) | 49 | 49 | 49 | 49 | 49 |
| composition | Polymer | YP-50 (Bis A-type phenoxy resin) | 30 | 30 | 30 | 30 | 30 |
| (parts by | component | VA-9310MF (Urethane resin) | | | | | |
| mass) | | SG-280EK23 (Acrylic resin) | | | | | |
| | Inorganic | AA-3 (Polyhedral alumina filler; | | | | 201 | |
| | filler | average particle diameter: 3.5 μm) | | | | | |
| | | AZ2-75 (Spherical alumina filler; | 378 | 570 | 708 | | 202 |
| | | average particle diameter: 3.0 μm) | | | | | |
| | | ASFP-05S (Spherical alumina filler; | 95 | 143 | 177 | | |
| | | average particle diameter: 0.6 μm) | | | | | |
| | Silane | KBM-403 (3-Glycidyloxytrimethoxysilane) | 1.3 | 2.0 | 2.4 | 0.2 | 0.4 |
| | coupling | KBM-1003 (Vinyltrimethoxysilane) | | | | | |
| | agent | KBM-903 (3-Aminopropyltrimethoxysilane) | | | | | |
| | | KBM-402 (3-Glycidyloxypropylmethyldimethoxysilane) | | | | | |
| | Curing agent | 2PHZ-PW (imidazole-type curing agent) | 8.5 | 8.5 | 8.5 | 8.5 | 8.5 |

| | | | | | |
|---|---|---|---|---|---|
| Total solid content (parts by mass) | 616 | 857 | 1030 | 344 | 345 |
| Inorganic filler loading amount (vol %) | 50.0 | 60.0 | 65.0 | 30.0 | 30.0 |
| Required amount (g) of silane coupling agent | 2.52 | 3.80 | 4.72 | 0.37 | 0.80 |
| Blending multiple of silane coupling agent | 0.5 | 0.5 | 0.5 | 0.5 | 0.5 |

| | | | | | |
|---|---|---|---|---|---|
| Melt viscosity at 120° C. (Pa · s) | 780 | 2100 | 5430 | 380 | 320 |
| Bulk thermal conductivity (W/m · K) | 1.5 | 2.0 | 2.6 | 1.2 | 1.0 |
| Die shear strength evaluation | A | A | A | A | A |
| Package assembly evaluation | A | A | A | AA | AA |
| Thermal conductivity (W/m · K) in package form | 1.1 | 1.4 | 1.8 | 0.9 | 0.7 |
| Evaluation of thermal conductivity in package form | A | A | AA | B | B |

TABLE 3

| | | | Comparative Example | | | | | |
|---|---|---|---|---|---|---|---|---|
| | | | 1 | 2 | 3 | 4 | 5 | 6 |
| Film | Epoxy resin | EPPN-501 H (Triphenylmethane-type epoxy resin) | 56 | 56 | 56 | 56 | 56 | 56 |
| adhesive | | YD-128 (liquid Bis A-type epoxy resin) | 49 | 49 | 49 | 49 | 49 | 49 |
| composition | Polymer | YP-50 (Bis A-type phenoxy resin) | 30 | 30 | 30 | 30 | 30 | 30 |
| (parts by | component | VA-9310MF (Urethane resin) | | | | | | |
| mass) | | SG-280EK23 (Acrylic resin) | | | | | | |
| | Inorganic | AA-3 (Polyhedral alumina filler; | 470 | 375 | 568 | 428 | 1160 | 377 |
| | filler | average particle diameter: 3.5 μm) | | | | | | |
| | | AA-05 (Polyhedral alumina; | | 94 | 142 | 107 | 290 | 94 |
| | | average particle diameter: 0.58 μm) | | | | | | |
| | Silane | KBM-403 (3-Glycidyloxytrimethoxysilane) | 0.4 | | 1.2 | | | 0.8 |
| | coupling agent | KBM-903 (3-Aminopropyltrimethoxysilane) | | | | 20.0 | 4.5 | |
| | Curing agent | 2PHZ-PW (imidazole-type curing agent) | 8.5 | 8.5 | 8.5 | 8.5 | 8.5 | 8.5 |

| | | | | | | |
|---|---|---|---|---|---|---|
| Total solid content (parts by mass) | 613 | 611 | 854 | 698 | 1597 | 615 |
| Inorganic filler loading amount (vol %) | 50.0 | 50.0 | 60.0 | 50.0 | 75.0 | 50.0 |
| Required amount (g) of silane coupling agent | 0.85 | 1.59 | 2.41 | 1.70 | 4.60 | 1.61 |
| Blending multiple of silane coupling agent | 0.5 | 0.0 | 0.5 | 11.8 | 1.0 | 0.5 |

| | | | | | | |
|---|---|---|---|---|---|---|
| Melt viscosity at 120° C. (Pa · s) | 840 | 950 | 2670 | 570 | 10500 | 765 |
| Bulk thermal conductivity (W/m · K) | 2.0 | 2.2 | 3.2 | 1.9 | 4.5 | 2.3 |
| Die shear strength evaluation | B | B | B | B | B | B |
| Package assembly | A | A | A | B | B | AA |
| Thermal conductivity (W/m · K) in package form | 0.9 | 0.9 | 2.4 | 0.8 | 0.5 | 1.9 |
| Evaluation of thermal conductivity in package form | B | B | AA | B | C | A |

### Notes in Tables

In the above Tables, the units of numerical values described in the rows of “Epoxy resin”, “Polymer component”, “Inorganic filler”, “Silane coupling agent”, and “Curing agent” are all “parts by mass”.

Reference Examples 1 to 3 have demonstrated that in the case of using the spherical alumina filler, even when the amount of spherical alumina filler blended is increased to 50 vol % or more, the die shear strength is 20 MPa or more in half or more of the samples in the die shear strength evaluation, and the averaged die shear strength is also high, indicating favorable adhesion strength.

Further, Reference Examples 4 and 5 have revealed that even in the case of using either the spherical alumina filler or the polyhedral alumina filler, the adhesion strength is favorable as long as the blending amount is about 30 vol %.

Meanwhile, it has been found that when the polyhedral alumina filler is used and the blending amount thereof is increased to 50 vol % or more, the average die shear strength is less than 20 MPa, resulting in poor adhesion strength (Comparative Examples 1 to 6).

By contrast, the film adhesives formed using the adhesive compositions of Examples 1 to 13 satisfying the requirements of the present invention had an average die shear strength of 20 MPa or more and a thermal conductivity in a package form of 1.0 W/m·K or more. Examples 3 to 11 containing 50 vol % or more of the polyhedral alumina filler as an inorganic filler are also excellent in the die shear strength and thermal conductivity in a package form. It has been found that use of the adhesive composition of the present invention allows for the formation of a film adhesive having a high strength of adhesion to an adherend and excellent thermal conductivity even when the polyhedral alumina filler as an inorganic filler is contained.

Furthermore, it has been demonstrated that the film adhesives of Examples 1 to 13 hardly form voids at the interface with an adherend, and are also excellent in package assembly.

Having described the present invention as related to the embodiment, it is our intention that the present invention not be limited by any of the details of the description, unless otherwise specified, but rather be construed broadly within its spirit and scope as set out in the accompanying claims.

### DESCRIPTION OF SYMBOLS

1 Semiconductor wafer
2 Adhesive layer (film adhesive)
3 Dicing film (dicing tape)
4 Semiconductor chip
5 Semiconductor chip with film adhesive
6 Circuit board
7 Bonding wire
8 Sealing resin
9 Semiconductor package

1. A thermally conductive film adhesive composition, comprising at least:
an epoxy resin (A),
an epoxy resin curing agent (B),
a polymer component (C),
a polyhedral alumina filler (D), and
a silane coupling agent (E),
wherein a percentage of the polyhedral alumina filler (D) to a total content of the epoxy resin (A), the epoxy resin curing agent (B), the polymer component (C), the polyhedral alumina filler (D), and the silane coupling agent (E) is from 20 to 70 vol %, and
wherein a blending multiple of the silane coupling agent as represented by the following (Formula I) is from 1.0 to 10:
Blending multiple of silane coupling agent=Blending amount(g) of silane coupling agent(E)/Required amount(g) of silane coupling agent(E) where (Formula I)
Required amount(g) of silane coupling agent(E)=[Blending amount(g) of polyhedral alumina filler(D)×Specific surface area(m²/g) of polyhedral alumina filler(D)]/Minimum coating area(m²/g) of silane coupling agent(E). (Formula II)

2. The thermally conductive film adhesive composition according to claim 1,
wherein when a thermally conductive film adhesive obtained from the thermally conductive film adhesive composition is heated at a temperature elevation rate of 5° C./min from 25° C., melt viscosity at 120° C. reaches a range of 250 to 10000 Pa·s, and
wherein the thermally conductive film adhesive has a thermal conductivity of 1.0 W/m·K or more.

3. The thermally conductive film adhesive composition according to claim 1, wherein the thermally conductive film adhesive has a die shear strength at 25° C. of 20 MPa or more.

4. The thermally conductive film adhesive composition according to claim 1, wherein a percentage of the polyhedral alumina filler (D) to a total content of the epoxy resin (A), the epoxy resin curing agent (B), the polymer component (C), the polyhedral alumina filler (D), and the silane coupling agent (E) is from 50 to 70 vol %.

5. A thermally conductive film adhesive which is obtained from the thermally conductive film adhesive composition according to claim 1.

6. The thermally conductive film adhesive according to claim 5, which has a thickness in a range of 1 to 80 μm.

7. A method of producing a semiconductor package, comprising:
a first step of providing an adhesive layer by thermocompression bonding the thermally conductive film adhesive according to claim 5 to a back surface of a semiconductor wafer in which a semiconductor circuit is formed on a surface, and providing a dicing film with the adhesive layer interposed between the back surface and the dicing film;
a second step of integrally dicing the semiconductor wafer and the adhesive layer to obtain a semiconductor chip with an adhesive layer, the semiconductor chip including the semiconductor chip and a piece of the film adhesive on the dicing film;
a third step of removing the dicing film from the semiconductor chip with an adhesive layer and thermocompression bonding the semiconductor chip with an adhesive layer and a circuit board via the adhesive layer; and
a fourth step of thermally curing the adhesive layer.

8. A semiconductor package which is obtained by the producing method according to claim 7.
